(19) United States
(12) Patent Application Publication
(10) Pub. No.: US 2009/0151973 A1
(43) Pub. Date: Jun. 18, 2009

(54) MOBILE DEVICE

(75) Inventors: Akihiro Fujimoto, Seto-city (JP); Norihisa Kataya, Kasugai-city (JP)

Correspondence Address: OSHA LIANG L.L.P., TWO HOUSTON CENTER, 909 FANNIN, SUITE 3500, HOUSTON, TX, 77010, US

(73) Assignee: OMRON CORPORATION, Kyoto-shi (JP)

(21) Appl. No.: 12/334,055

(22) Filed: Dec. 12, 2008

(30) Foreign Application Priority Data
Dec. 13, 2007 (JP) 2007-321503

(51) Int. Cl. H05K 5/06

(52) U.S. Cl. 174/50.5

(57) ABSTRACT

A mobile device has a push-button type operation unit at a side surface of a body case. The body case has a dual-partitioned structure of a first case and a second case. The first case includes a main portion having a plane substantially parallel to a partitioning surface of the cases, and a side wall extending in a direction substantially orthogonal to the main portion from four side ends of the main portion. The side wall and the second case are separably coupled. A waterproof rubber is attached on an inner side of the main portion and the side wall of the first case. An electronic circuit substrate mounted with a switch corresponding to the operation unit is at least accommodated on an inner side of the waterproof rubber. The waterproof rubber includes a sandwiching portion inserted to a bonding site of the first case and the second case, and a side wall interposed between the operation unit and the switch.

### BACKGROUND OF THE INVENTION

1. Technical Field

The present invention relates to mobile devices and, more specifically, to a waterproof structure of a mobile device used outdoors.

2. Related Art

Although not particularly limited, a remote controller device in a remote keyless entry system and the like of a vehicle such as an automobile is known as one example of a mobile device used outdoors. The remote keyless entry system is a convenient system that can lock/unlock a door by simply operating a push button of the mobile device (remote controller device) without using a mechanical key.

With such a mobile device, waterproof countermeasures in rain and the like are essential as the mobile device is used outdoors, and a “portable terminal” disclosed in Japanese Unexamined Patent Publication No. 2006-48092, for example, has been known as prior art related to the waterproof structure.

FIGS. 6A to 6C show views showing a waterproof structure of the prior art. In the figure, FIG. 6A shows a perspective view of an outer appearance of the portable terminal, FIG. 6B shows a cross-sectional view of the main parts, and FIG. 6C shows a cross-sectional view showing a waterproof packing.

As shown in FIG. 6A, a portable terminal 1 of the prior art has an exterior rubber 4 made from elastic raw material attached while covering an entire periphery of a side surface of a body case 3 including a liquid crystal display panel 2 on a front surface, where an operation unit 5 in the form of a push button is formed at a main part of the exterior rubber 4. The operation unit 5 is formed at three locations: the right side surface A, the upper surface B, and the left side surface C of the exterior rubber 4, but only the right side surface A will be described for the sake of convenience of a description.

As shown in FIG. 6B, the body case 3 is formed with an opening 6 facing the operation unit 5, where an operator 9 of a switch 8 attached to a substrate 7 peeks out from the opening 6. A projection 10 is formed on a back surface (surface facing the opening 6) of the operation unit 5, and a distal end of the projection 10 indirectly contacts a distal end of the operator 9 of the switch 8 by way of a waterproof packing 11, which closes the opening 6.

As shown in FIG. 6C, the packing 11 has a substantially plate-shaped cross-section, and is configured by a bottom 12, and a side wall 13 upstanding from the periphery of the bottom 12. The bottom 12 and the side wall 13 are integrally formed, but the thickness thereof differs from each other, and more specifically, the thickness of the bottom 12 is made thin with respect to the thickness of the side wall 13.

In such a configuration, when the operation unit 5 of the exterior rubber 4 is pushed, an operation force thereof is transmitted in the order of projection 10 of the exterior rubber 4→bottom 12 of the packing 11→operator 9 of the switch 8, whereby the operator 9 of the switch 8 is pushed in, and the switch 8 transitions to an ON or an OFF state.

Water such as rainwater entered from a gap between the body case 3 and the exterior rubber 4 attempts to enter an interior of the body case 3 through the opening 6 of the body case 3, but water does not further enter since the opening 6 is closed by the packing 11, whereby the waterproof countermeasure is achieved.

### SUMMARY

However, in the prior art, the packing 11 of the same number as the operation unit 5 (opening 6) is required (e.g., three operation units are arranged in the prior art, and thus three packings 11 are required), which leads to increase in the number of parts and increase in an assembling man-hours, and consequently, increase in a manufacturing cost becomes inevitable.

One or more embodiments of the present invention to provides a mobile device having a waterproof structure that avoids increase in the number of parts and increase in the assembling man-hours, and furthermore, increase in the manufacturing cost.

According to one or more embodiments of the present invention, a mobile device includes a push-button type operation unit at a side surface of a body case; wherein the body case has a dual-partitioned structure of a first case and a second case; the first case includes a main portion having a plane substantially parallel to a partitioning surface of the cases, and a side wall extending in a direction substantially orthogonal to the main portion from four side ends of the main portion, the side wall and the second case being separably coupled; a waterproof rubber is attached on an inner side of the main portion and the side wall of the first case; an electronic circuit substrate mounted with a switch corresponding to the operation unit is at least accommodated on an inner side of the waterproof rubber; and the waterproof rubber includes a sandwiching portion inserted to a bonding site of the first case and the second case, and a side wall interposed between the operation unit and the switch.

According to one or more embodiments of the present invention, a thickness of the side wall of the waterproof rubber interposed between the operation unit and the switch is set relatively large so that durability of the waterproof rubber does not lower with repeated operation of the operation unit.

According to one or more embodiments of the present invention, a member for preventing inward slant of the waterproof rubber is accommodated on the inner side of the waterproof rubber and in the vicinity of the sandwiching portion.

According to one or more embodiments of the present invention, the member for preventing the inward slant is a battery accommodation substrate.

In one or more embodiments of the present invention, waterproof between the first case and the second case is realized by the waterproof rubber, and the waterproof between the operation unit on the side surface of the body case and the switch is also realized by the side wall of the waterproof rubber. Therefore, according to one or more embodiments of the present invention, only one waterproof rubber is required regardless of the number of operation units (switches), whereby a mobile device that avoids increase in the number of parts and increase in the assembling man-hours, and furthermore, increase in the manufacturing cost can be provided.

### BRIEF DESCRIPTION OF THE DRAWINGS

FIGS. 1A and 1B show outer appearance views of a mobile device 20 according to an embodiment;

FIG. 2 shows a cross-sectional view (cross sectional view taken along line A-A of FIG. 1) of the mobile device 20;

FIGS. 3A to 3C show cross-sectional views showing an assembled state of the mobile device 20;

FIG. 4 shows a cross-sectional view of main parts showing a first additional effect;

FIG. 5 shows a cross-sectional view of main parts showing a second additional effect; and

FIGS. 6A to 6C show views of a waterproof structure according to prior art.

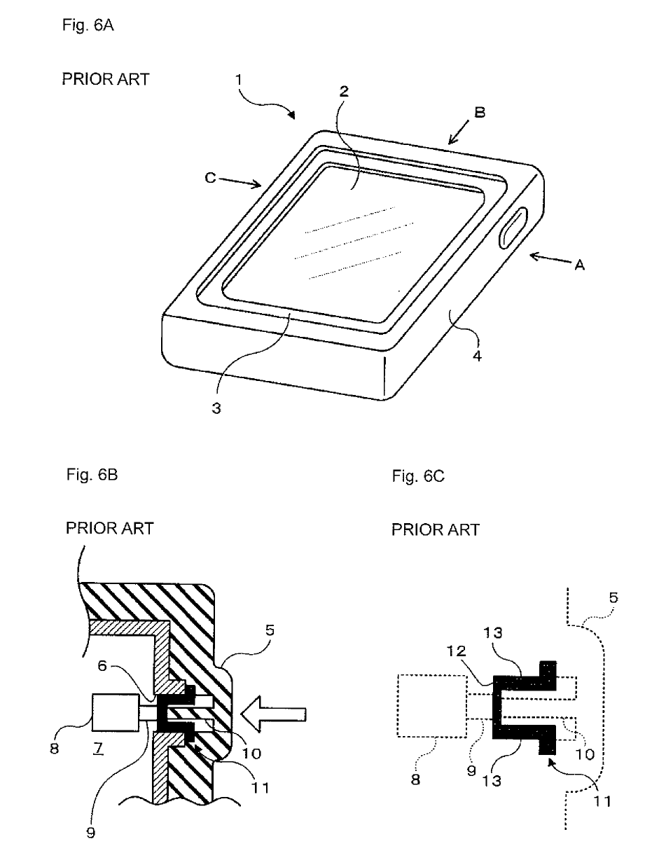

### DETAILED DESCRIPTION

Application of an embodiment of the present invention to a remote controller device (hereinafter referred to as a mobile device) of a remote keyless entry system will be described by way of example with reference to the drawings.

First, an outer appearance of a mobile device 20 according to the present embodiment will be discussed.

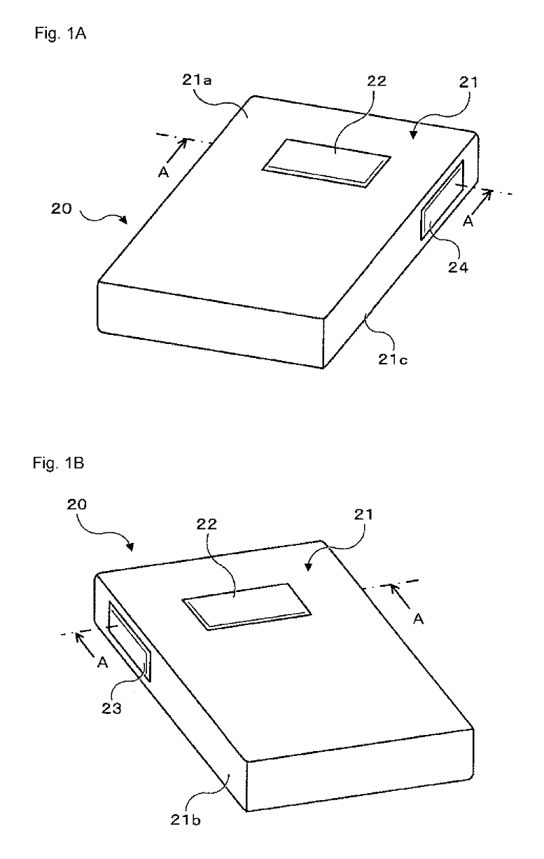

FIGS. 1A and 1B show outer appearance views of the mobile device 20. Here, FIG. 1A shows an outer appearance view of the mobile device 20 seen diagonally from the right, and FIG. 1B shows an outer appearance view of the mobile device 20 seen diagonally from the left, where both figures show perspective views of the outer appearance of the mobile device 20.

The mobile device 20 includes a push-button type operation unit (hereinafter referred to as first to third operation units 22 to 24) arranged on a front surface 21a, and left and right side surfaces 21b, 21c of a body case 21, where such first to the third operation units 22 to 24 are selectively pushed to lock/unlock a door, or open/close a slide door of a vehicle such as an automobile mounted with a receiver that forms a pair with the mobile device 20 (have same ID identification information).

The illustrated mobile device 20 includes one operation unit (first operation unit 22) arranged on the front surface 21a, one operation unit (second operation unit 23) arranged on the left side surface 21b, and one operation unit (third operation unit 24) arranged on the right side surface 21c, that is, a total of three operation units (first to third operation units 22 to 24), but one example of the arrangement of the operation units is merely shown. The operation unit at each surface is not limited to one, and may be two or more units.

Although not particularly limited, the illustrated three operation units (first to third operation units 22 to 24) are used for the following applications for the sake of convenience of a description. Specifically, the first operation unit 22 on the front surface 21a is used to lock/unlock the door, the second operation unit 23 on the left side surface 21b is used to open/close a left slide door, and the third operation unit 24 on the right side surface 21c is used to open/close a right slide door.

The structure of the mobile device 20 will be described below.

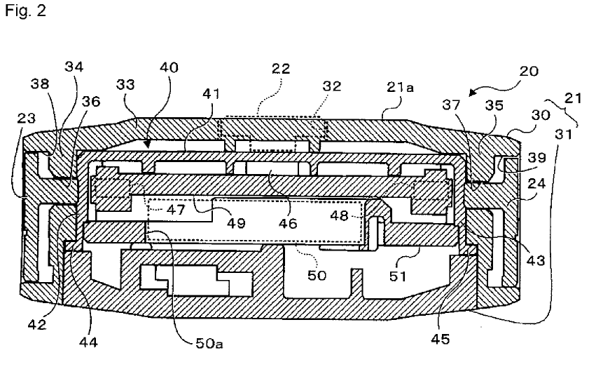

FIG. 2 shows a cross-sectional view (cross sectional view taken along line A-A of FIG. 1) of the mobile device 20. The body case 21 of the mobile device 20 has an upper and lower partitioned structure including a case (hereinafter referred to as a first case 30) on an upper side (upper surface 21a side arranged with the first operation unit 22 for locking/unlocking the door) facing the drawing, and a case (hereinafter referred to as a second case 31) on a lower side.

The first case 30 is configured by integrally forming a main portion 33 including an attachment hole 32 for attaching the first operation unit 22 for locking/unlocking the door and having a plane substantially parallel to a partitioning surface of the cases (first case 30 and second case 31); and side walls 34, 35 (only left and right side walls 34, 35 are drawn in the figure but this is for the sake of convenience of illustration, and actually, the side walls are also arranged on the upper end side of the case in the far direction of the drawing and on the lower end side of the case in the near direction of the figure, respectively) arranged projecting in a direction (lower side in the figure) substantially orthogonal to the main portion 33 from four side ends of the main portion 33 and extending over the entire periphery of the side ends of the main portion 33, and furthermore, openings 36, 37 are formed in the left and right side walls 34, 35, respectively, and recesses 38, 39 for attaching the second operation unit 23 and the third operation unit 24 are formed on an outer side of the left and right side walls 34, 35, respectively.

The second case 31 plays a role of a “lid” for closing a space surrounded by the side walls 34, 35 on the four sides of the first case 30, where the second case 31 and the first case 30 are a separable coupling type (e.g., fit in type).

A waterproof rubber 40 made from an elastic raw material is attached on the inner side of the first case 30, which waterproof rubber 40 has a recessed shape substantially covering the inner surface of the first case 30. That is, the waterproof rubber 40 is configured by integrally forming a main portion 41 substantially parallel to the main portion 33 of the first case 30; side walls 42, 43 (only left and right side walls 42, 43 are drawn in the figure but this is for the sake of convenience of illustration, and actually, the side walls are also arranged on the upper end side of the case in the far direction of the drawing and on the lower end side of the case in the near direction of the figure, respectively) extending in a direction (lower side in the figure) substantially orthogonal to the main portion 41 from four side ends of the main portion 41; and sandwiching portions 44, 45 formed so as to slightly protrude to the outer side at the edge of the side walls 42, 43 on the four sides.

On the inner side of the waterproof rubber 40, one switch (hereinafter referred to as a first switch 46) is arranged on the upper surface, and switches 47, 48 (hereinafter referred to as a second switch 47 and a third switch 48) are arranged on the left and right ends, respectively, and an electronic circuit mounting substrate 49 mounted with an electronic circuit (not shown), as well as a battery accommodation substrate 51 with a battery attachment portion 50a for attaching a battery (typically, button-shaped battery) 50 are accommodated therein, in order from the top of the drawing.

The first switch 46 is positioned on the lower side of the first operation unit 22 for locking/unlocking the door attached to the main portion 33 of the first case 30, and is turned ON and OFF by pushing the first operation unit 22. Therefore, the first switch 46 functions as a switch for locking/unlocking the door. The second switch 47 positioned on the left side of the electronic circuit mounting substrate 49 faces the second operation unit 23 attached on the outer side of the left side wall 34 by way of the left side wall 42 of the waterproof rubber 40, and is turned ON and OFF by pushing the second operation unit 23. Therefore, the second switch 47 functions as a switch for opening/closing the left slide door. The third switch 48 positioned on the right side of the electronic circuit mounting substrate 49 faces the third operation unit 24 attached on the outer side of the right side wall 35 by way of the right side wall 43 of the waterproof rubber 40, and is turned ON and OFF by pushing the third operation unit 24. Therefore, the third switch 48 functions as a switch for opening/closing the right slide door.

Characteristic configurations of the mobile device 20 of the present embodiment are listed below.

(1) The sandwiching portions 44, 45 of the waterproof rubber 40 are inserted to the bonding site of the first case 30 and the second case 31. Thus, the cases are sealed by the sandwiching portions 44, 45 of the waterproof rubber 40, and waterproof countermeasures between the first case 30 and the second case 31 is achieved.

(2) The main portion 41 of the waterproof rubber 40 is interposed between the switch for locking/unlocking the door (first switch 46) and the operation unit (first operation unit 22) for locking/unlocking the door. Thus, even if rainwater and the like enters from the attachment hole 32 for attaching the first operation unit 22 for locking/unlocking the door of the first case 30 by any possibility, the rainwater can be inhibited by the main portion 41 of the waterproof rubber 40, and waterproof countermeasures on the switch for locking/unlocking the door (first switch 46) is achieved.

(3) The left side wall 42 of the waterproof rubber 40 is interposed between the switch for opening/closing the left slide door (second switch 47) and the operation unit (second operation unit 23) for opening/closing the left slide door. Thus, even if rainwater and the like enters from the opening 36 of the left side wall 34 of the first case 30 by any possibility, the rainwater can be inhibited by the side wall 42 of the waterproof rubber 40, and waterproof countermeasures on the switch for opening/closing the left slide door (second switch 47) is achieved.

(4) The right side wall 43 of the waterproof rubber 40 is interposed between the switch for opening/closing the right slide door (third switch 48) and the operation unit (third operation unit 24) for opening/closing the right slide door. Thus, even if rainwater and the like enters from the opening 37 of the right side wall 35 of the first case 30 by any possibility, the rainwater can be inhibited by the side wall 45 of the waterproof rubber 40, and waterproof countermeasures on the switch for opening/closing the right slide door (third switch 48) is achieved.

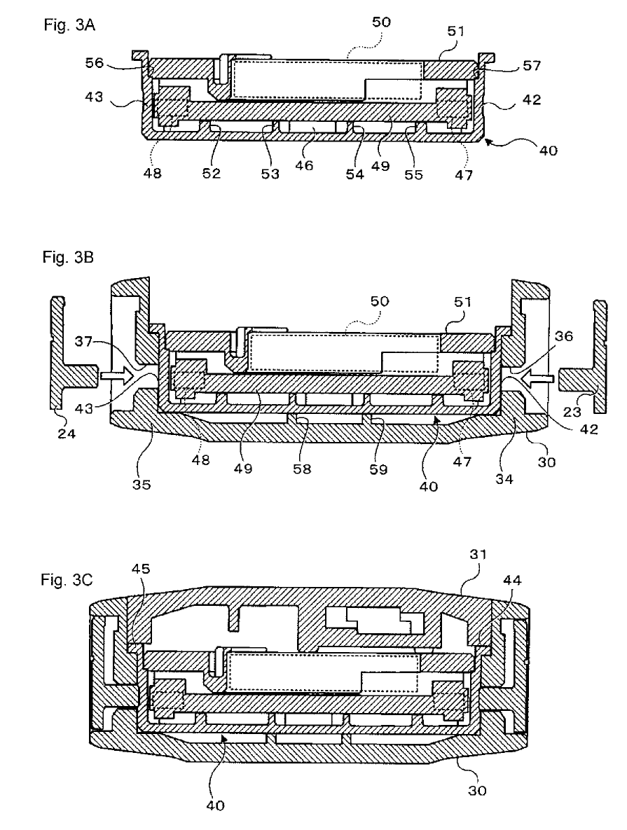

FIGS. 3A to 3C show cross-sectional views showing an assembled state of the mobile device 20. This figure shows the cross-sectional view of FIG. 2 in an upside down manner. That is, the first case 30 is drawn on the bottom, and the second case 31 is drawn on the top.

<FIG. 3A>

When assembling the mobile device 20, first, the waterproof rubber 40 is set to a state opened upward, and the first to the third switches 46 to 48, and the electronic circuit mounting substrate 49 mounted with the electronic circuit (not shown) are accommodated in the waterproof rubber 40. A plurality of projections 52 to 55 for holding the substrate are arranged upright at the bottom of the waterproof rubber 40, where the electronic circuit mounting substrate 49 accommodated in the waterproof rubber 40 sits on the projections 52 to 55.

The battery accommodation substrate 51 attached with the battery 50 is then placed in the waterproof rubber 40. Steps 56, 57 are formed at the side walls 42, 43 of the waterproof rubber 40, so that the battery accommodation substrate 51 accommodated in the waterproof rubber 40 is caught at the steps 56, 57 so as not to move any further in the downward direction (direction of electronic circuit mounting substrate 49).

<FIG. 3B>

After the electronic circuit mounting substrate 49 and the battery accommodation substrate 51 are accommodated on the inner side of the waterproof rubber 40, the waterproof rubber 40 is accommodated in the first case 30 opened upward. A plurality of projections 58, 59 for holding the waterproof rubber is arranged upright at the bottom of the first case 30, so that the waterproof rubber 40 accommodated in the first case 30 sits on the projections 58, 59.

The second operation unit 23 and the third operation unit 24 are respectively attached from the outer side to the openings 36, 37 formed at the left and the right side walls 34, 35 of the first case 30. The second operation unit 23 and the third operation unit 24, and the two switches (second switch 47, third switch 48) of the electronic circuit mounting substrate 49 then indirectly face each other by way of the side walls 42, 43 of the waterproof rubber 40 by such attachment.

<FIG. 3C>

Finally, the second case 31 is inserted from the opened surface side of the first case 30, the cases are fitted to each other, and the opened surface of the first case 30 is closed. In this case, the sandwiching portions 44, 45 of the waterproof rubber 40 are inserted to the bonding surface of the first case 30 and the second case 31.

Through the configuration described above, waterproof countermeasures between the first case 30 and the second case 31 is taken by the waterproof rubber 40, and in addition, following peculiar effects are obtained according to the mobile device 20 of the present embodiment.

(I) Since the side wall 42 and the side wall 43 of the waterproof rubber 40 are interposed between the second operation unit 23 and the third operation unit 24 arranged on the side surfaces of the body case 21, and the second switch 47 and the third switch 48 mounted on the electronic circuit mounting substrate 49, respectively, even if rainwater and the like enters from the attachment hole (opening 36) of the second operation unit 23 or the attachment hole (opening 37) of the third operation unit 24 by any possibility, the rainwater is inhibited by the side wall 42 or the side wall 43, and reliable waterproof countermeasures can be taken.

(II) Furthermore, since only one waterproof rubber 40 of the present embodiment is necessary regardless of the number of the first to the third operation units 22 to 24 and the switches (first to third switches 46 to 48), the drawbacks of the prior art, that is, leading to increase in the number of parts and increase in the assembling man-hours, and consequently, inevitably leading to increase in the manufacturing cost do not arise.

The embodiment described above also has additional effects described below.

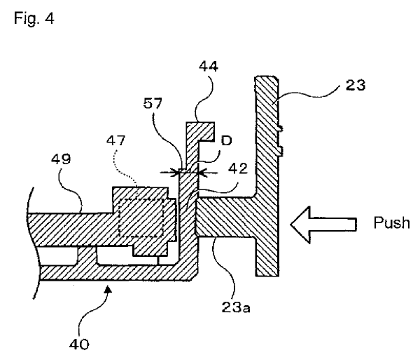

FIG. 4 shows a cross-sectional view of main parts showing a first additional effect. As shown in the figure, when the operation unit arranged on the side surface of the body case 21 (second operation unit 23 is given by way of example for the sake of convenience in the figure) is pushed, the side wall 42 of the waterproof rubber 40 is pushed in towards the left in the figure by a projection 23a at the root of the second operation unit 23, and the second switch 47 mounted on the electronic circuit mounting substrate 49 is turned ON therewith. In this case, stress in the pushing direction applies on the side wall 42 of the waterproof rubber 40, and thus troubles such as breakage of the side wall 42 of the waterproof rubber 40 may arise if such push operation is repeated. In order to respond to such trouble, the thickness of the side wall 42 of the waterproof rubber 40 (specifically, thickness D of the portion the projection 23a of the second operation unit 23 contacts) is made slightly large in the present embodiment. It is not necessarily appropriate to suggest the appropriate thickness D, but since the operation feeling of the second operation unit 23 is affected if the thickness D is too large, the thickness is set by trial and error by obtaining a point of compromise between durability of the waterproof rubber 40 and satisfactory operation feeling.

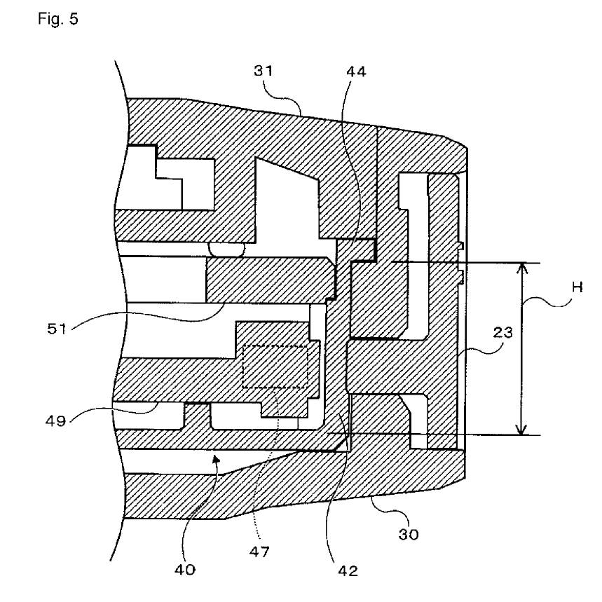

FIG. 5 shows a cross-sectional view of main parts showing a second additional effect. The waterproof rubber 40 of the present example has a recessed shape, and the height H of the side walls 42, 43 at the four sides is set large. Thus, after the assembly of the mobile device 20 is completed, “inward slant” may occur at the side walls 42, 43 of the waterproof rubber 40 with the push operation of the second operation unit 23 and the third operation unit 24. If such inward slant occurs, the sandwiching portions 44, 45 of the waterproof rubber 40 may detach from the bonding site of the first case 30 and the second case 31 in the worst case, in which case, the waterproof effect is lost, and thus some kind of countermeasures needs to be taken. As a countermeasure, the battery accommodation substrate 51 is arranged near the sandwiching portions 44, 45 of the waterproof rubber 40 in the present embodiment. That is, the sandwiching portions 44, 45 are sandwiched by the side walls 34, 35 and the battery accommodation substrate 51. The inward slant is thereby prevented, and loss of waterproof effect can be avoided.

In the above description, application to the remote controller device of the remote keyless entry system has been given by way of example, but is not limited thereto. The application merely needs to be on a mobile device having a push-button type operation unit on the side surface and particularly requiring waterproof countermeasures such as electronic equipment including a personal digital assistant having the possibility of being used outdoors and the like. Furthermore, waterproof countermeasures of rainwater and the like has been described in the above description, but is not limited to “waterproof countermeasures”, and application obviously can be made on “dustproof countermeasures” for inhibiting entering of fine dust.

What is claimed is:

1. A mobile device comprising a push-button type operation unit at a side surface of a body case; wherein
the body case has a dual-partitioned structure of a first case and a second case;
the first case includes a main portion having a plane substantially parallel to a partitioning surface of the cases, and a side wall extending in a direction substantially orthogonal to the main portion from four side ends of the main portion, the side wall and the second case being separably coupled;
a waterproof rubber is attached on an inner side of the main portion and the side wall of the first case;
an electronic circuit substrate mounted with a switch corresponding to the operation unit is at least accommodated on an inner side of the waterproof rubber; and
the waterproof rubber includes a sandwiching portion inserted to a bonding site of the first case and the second case, and a side wall interposed between the operation unit and the switch.

2. The mobile device according to claim 1, wherein a thickness of the side wall of the waterproof rubber interposed between the operation unit and the switch is set relatively large so that durability of the waterproof rubber does not lower with repeated operation of the operation unit.

3. The mobile device according to claim 1, wherein a member for preventing inward slant of the waterproof rubber is accommodated on the inner side of the waterproof rubber and in the vicinity of the sandwiching portion.

4. The mobile device according to claim 3, wherein the member for preventing the inward slant is a battery accommodation substrate.
